(19) United States
(12) Patent Application Publication
(10) Pub. No.: US 2011/0284281 A1
(43) Pub. Date: Nov. 24, 2011

(54) LAMINATED HIGH-FREQUENCY MODULE

(75) Inventor: Takahiro AKIYAMA, Nagaokakyo-shi (JP)

(73) Assignee: MURATA MANUFACTURING CO., LTD., Nagaokakyo-shi (JP)

(21) Appl. No.: 13/109,030

(22) Filed: May 17, 2011

(30) Foreign Application Priority Data
May 20, 2010 (JP) 2010-116146

(51) Int. Cl. H05K 1/11

(52) U.S. Cl. 174/264

(57) ABSTRACT

In a laminated high-frequency module, a laminate includes a plurality of dielectric layers. In a lower layer region including some of the plurality of dielectric layers, a digital circuit is provided. In an interlayer region including some of the plurality of dielectric layers, a digital circuit and an analog circuit are arranged so that they do not overlap in plan view of the laminate. In an upper layer region including some of the plurality of dielectric layers, a digital circuit is provided. Digital ICs are mounted on the surface of the uppermost dielectric layer in the upper layer region. An inner-layer ground electrode is provided on substantially an entire boundary surface between the lower layer region and the interlayer region and on substantially an entire boundary surface between the interlayer region and the upper layer region. In the interlayer region, a digital line and an inner-layer ground electrode are alternately arranged in the lamination direction.

### BACKGROUND OF THE INVENTION

1. Field of the Invention

The present invention relates to a laminated high-frequency module obtained by integrating a high-frequency circuit having a predetermined function with a laminate and an IC on the laminate.

2. Description of the Related Art

Various high-frequency modules capable of meeting a plurality of communication specifications have been proposed. Some of the high-frequency modules include a digital IC for Bluetooth (registered trademark) and for Wireless LAN (W-LAN). When such a digital IC is used, it is necessary to provide a digital circuit portion including the digital IC and an analog circuit portion including an RF processing unit, such as a band-pass filter (BPF) in a high-frequency module. In this case, if electromagnetic interference between the digital circuit portion and the analog circuit portion is not prevented, the characteristics of the high-frequency module are degraded.

In the high-frequency module disclosed in Japanese Unexamined Patent Application Publication No. 11-145570, a digital circuit portion and an analog circuit portion are completely separated so that ground electrodes thereof overlap in plan view.

However, in the high-frequency module disclosed in Japanese Unexamined Patent Application Publication No. 11-145570 including the digital circuit portion and the analog circuit portion that are completely separated, for example, even if the digital circuit portion has space available for formation of an analog circuit, the analog circuit cannot be formed in the space. Therefore, it is difficult to sufficiently reduce the size of the high-frequency module.

### SUMMARY OF THE INVENTION

To overcome the problems described above, preferred embodiments of the present invention provide a small laminated high-frequency module including an analog circuit portion and a digital circuit portion without degrading the characteristic of the laminated high-frequency module.

A laminated high-frequency module according to a preferred embodiment of the present invention preferably includes a laminate of dielectric layers each including an upper surface and a lower surface on at least one of which a predetermined electrode pattern is provided. A digital circuit electrode pattern is provided in an upper layer region and a lower layer region in the laminate. The digital circuit electrode pattern and an analog circuit electrode pattern are provided in an interlayer region sandwiched between the upper layer region and the lower layer region in a lamination direction. In the interlayer region, a digital circuit electrode pattern formation region and an analog circuit electrode pattern formation region preferably do not overlap in plan view of the laminate. A first inner-layer ground electrode is provided on substantially an entire surface of one of the dielectric layers between the interlayer region and the upper layer region and on substantially an entire surface of one of the dielectric layers between the interlayer region and the lower layer region in plan view of the laminate.

In the laminated high-frequency module, a digital circuit portion and an analog circuit portion are provided in a single laminate. In the interlayer region, since the digital circuit electrode pattern formation region and the analog circuit electrode pattern formation region do not overlap in plan view of the laminate, the electromagnetic coupling between the digital circuit electrode pattern and the analog circuit electrode pattern is prevented. The analog circuit electrode pattern formation region in the interlayer region and a digital circuit electrode pattern formation region in the upper layer region and the lower layer region overlap in plan view of the laminate. However, since a ground electrode is disposed on substantially an entire boundary surface between the interlayer region and the upper layer region and on substantially an entire boundary surface between the interlayer region and the lower layer region, the electromagnetic coupling between the analog circuit electrode pattern in the interlayer region and each of the digital circuit electrode patterns in the upper layer region and the lower layer region is also prevented.

In the laminated high-frequency module, the digital circuit electrode pattern is preferably provided on a plurality of the dielectric layers in the interlayer region, and a second inner-layer ground electrode is preferably provided between the digital circuit electrode patterns on the dielectric layers in the interlayer region.

The digital circuit electrode pattern on a dielectric layer in the interlayer region is more strongly coupled to the second inner-layer ground electrode overlapping the digital circuit electrode pattern in plan view of the laminate than to the analog circuit electrode pattern. Accordingly, the electromagnetic coupling between the digital circuit electrode pattern and the analog circuit electrode pattern is more effectively prevented.

In the laminated high-frequency module, the second inner-layer ground electrode is preferably provided in only the digital circuit electrode pattern formation region as viewed from the lamination direction.

Since the second inner-layer ground electrode and the analog circuit electrode pattern do not overlap in plan view of the laminate, the electromagnetic coupling between the second inner-layer ground electrode and the analog circuit electrode pattern is prevented.

In the laminated high-frequency module, an electrode formation density at which the digital circuit electrode pattern is provided in each of the upper layer region and the lower layer region is preferably greater than that at which the digital circuit electrode pattern is provided in the interlayer region.

By forming the digital circuit electrode pattern at a high density in the upper layer region and the lower layer region in which the analog circuit electrode pattern is not provided and between which the interlayer region is sandwiched via the first inner-layer ground electrodes, not only the prevention of the electromagnetic coupling between the analog circuit electrode pattern and the digital circuit electrode pattern but also a reduction in the profile and size of the laminate are achieved.

In the laminated high-frequency module, in the interlayer region, a first conductive via connected to the first inner-layer ground electrode is preferably provided between the digital circuit electrode pattern formation region and the analog circuit electrode pattern formation region.

Since the conductive via connected to the ground is provided between the digital circuit electrode pattern and the analog circuit electrode pattern in the interlayer region, the electromagnetic coupling between the digital circuit electrode pattern and the analog circuit electrode pattern in the interlayer region is more effectively prevented.

In the laminated high-frequency module, in the analog circuit electrode pattern formation region in the interlayer region, a second conductive via connected to the first inner-layer ground electrode is preferably provided on a side of a side surface of the laminate as viewed from the lamination direction.

Since the analog circuit electrode pattern is sandwiched between the conductive vias connected to the ground, the electromagnetic coupling between the analog circuit electrode pattern and another circuit element, for example, the digital circuit electrode pattern in the upper layer region or the lower layer region or the IC mounted on the laminate, or a circuit element outside the laminate is prevented.

In the laminated high-frequency module, in the digital circuit electrode pattern formation region in the interlayer region, a plurality of third conductive vias each connected to the first inner-layer ground electrode or the second inner-layer ground electrode are preferably provided.

Since a plurality of conductive vias connected to the ground are disposed near the digital circuit electrode pattern in the interlayer region, the ground characteristic of a digital circuit in the interlayer region is stabilized and the electromagnetic coupling between the digital circuit electrode pattern and another circuit element is more effectively prevented.

According to various preferred embodiments of the present invention, a small laminated high-frequency module that includes an analog circuit portion and a digital circuit portion and that has excellent communication characteristics is provided.

The above and other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram of a laminated high-frequency module according to a preferred embodiment of the present invention.

FIG. 2 is a side cross-sectional view of a laminated high-frequency module according to a preferred embodiment of the present invention.

FIG. 3 is a plan view of each layer in a laminated high-frequency module according to a preferred embodiment of the present invention.

### DETAILED DESCRIPTION OF THE PREFERRED EMBODIMENTS

A laminated high-frequency module according to preferred embodiments of the present invention will be described with reference to the accompanying drawings. In a preferred embodiment of the present invention, a laminated high-frequency module for transmitting and receiving an FM modulation communication signal, a Bluetooth communication signal, and a W-LAN communication signal will be described.

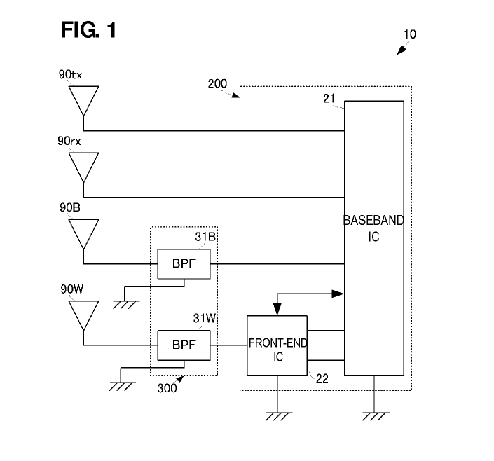

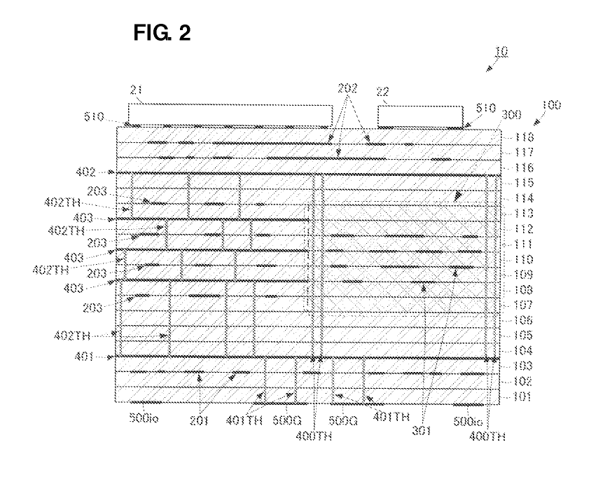

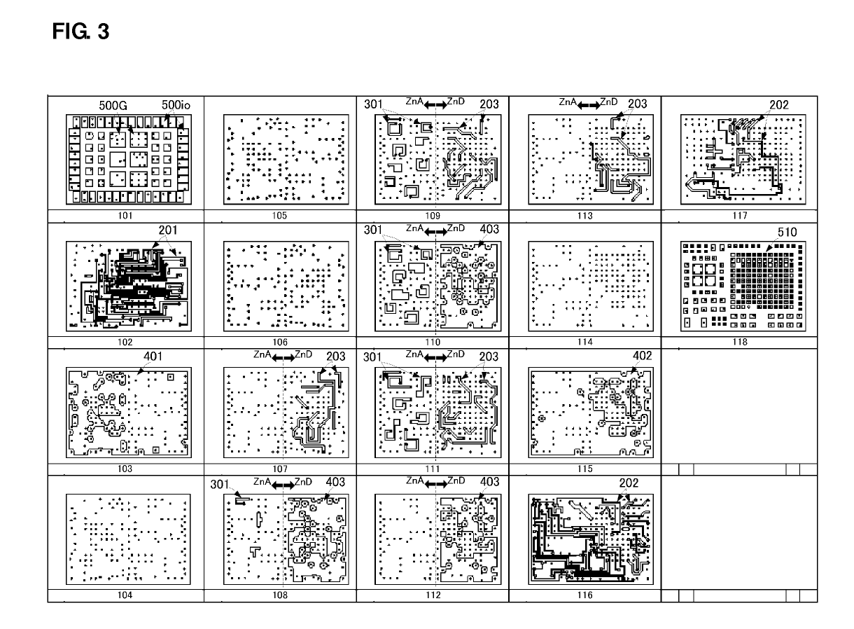

FIG. 1 is a circuit diagram of a laminated high-frequency module 10 according to a preferred embodiment of the present invention. FIG. 2 is a side cross-sectional view of a laminated high-frequency module 10 according to a preferred embodiment of the present invention. FIG. 3 is a plan view of each layer in a laminated high-frequency module 10 according to a preferred embodiment of the present invention.

The laminated high-frequency module 10 preferably includes a digital circuit portion 200 and an analog circuit portion 300. The digital circuit portion 200 preferably includes a baseband IC 21 and a front-end IC 22 that are digital circuit ICs. The analog circuit portion 300 preferably includes bandpass filters (BPFs) 31B and 31W.

The baseband IC 21 is driven with power from a DC-DC converter (not illustrated). The baseband IC 21 transmits an FM signal via an antenna 90tx and receives an FM signal via an antenna 90rx. The baseband IC 21 transmits and receives a Bluetooth communication signal via the BPF 31B and an antenna 90B. The baseband IC 21 transmits and receives a W-LAN communication signal via the front-end IC, the BPF 31W, and an antenna 90W.

The front-end IC 22 preferably includes a switch IC, an amplifier, a filter, and other circuit elements. When a W-LAN communication signal is transmitted, the front-end IC 22 performs filter processing and amplification processing on a W-LAN communication signal from the baseband IC 21 and outputs the processed W-LAN communication signal to the BPF 31W. When a W-LAN communication signal is received, the front-end IC 22 performs filter processing on a W-LAN communication signal from the BPF 31W and outputs the processed W-LAN communication signal to the baseband IC 21.

The laminated high-frequency module 10 including the digital circuit portion 200 and the analog circuit portion 300 is obtained with a laminate 100 and surface-mounted circuit elements, corresponding to the baseband IC 21 and the front-end IC 22, mounted on the top surface of the laminate 100 as illustrated in FIG. 2.

The laminate 100 includes a plurality of laminated dielectric layers. In a preferred embodiment of the present invention, as illustrated in FIGS. 2 and 3, the laminate 100 preferably includes eighteen dielectric layers 101 to 118. Via holes arranged to be connected to the ground are provided. Although not illustrated in FIGS. 2 and 3, a plurality of via holes are provided in each of the dielectric layers 101 to 118 in the laminate 100 so that the circuit in the laminated high-frequency module 10 illustrated in FIG. 1 is obtained.

On the lower surface of the dielectric layer 101 that is the lowermost layer in the laminate, a plurality of external-connection lands 500io and a plurality of external ground electrodes 500G are preferably provided. The external-connection lands 500io are arranged along edges of the lower surface of the dielectric layer 101. The external ground electrodes 500G are arranged at the approximate center of the lower surface of the dielectric layer 101.

The dielectric layer 102 is preferably disposed on the upper surface of the dielectric layer 101. On substantially the entire upper surface of the dielectric layer 102, a digital circuit electrode pattern 201 is preferably provided.

The dielectric layer 103 is preferably disposed on the upper surface of the dielectric layer 102. On substantially the entire upper surface of the dielectric layer 103, an inner-layer ground electrode 401 (corresponding to a first inner-layer ground electrode according to a preferred embodiment of the present invention) is preferably provided. The inner-layer ground electrode 401 is connected to the external ground electrodes 500G via a plurality of conductive vias 401TH provided in the dielectric layers 101 to 103.

No electrode pattern is provided on the dielectric layers 104, 105, and 106. The dielectric layers 104, 105, and 106 are laminated in this order on the upper surface of the dielectric layer 103, and are preferably used to adjust the spacing between each of a digital circuit electrode pattern 203 and an analog circuit electrode pattern 301, which will be described later, and the inner-layer ground electrode 401 provided on the dielectric layer 103. By appropriately setting the number of laminated dielectric layers having no electrode pattern and the thicknesses of these layers, for example, the analog circuit electrode pattern 301 and the inner-layer ground electrode 401 are preferably arranged at a predetermined spacing so that a predetermined element value of each circuit element (an inductor or a capacitor) provided by the analog circuit electrode pattern 301 is set.

The laminate including the dielectric layers 101 to 103 corresponds to a lower layer region according to a preferred embodiment of the present invention.

The dielectric layer 107 is disposed on the upper surface of the dielectric layer 106. The upper surface of the dielectric layer 107 is preferably approximately equally divided into two regions. In one of these regions, the digital circuit electrode pattern 203 is provided. This region is hereinafter referred to as a digital wiring region ZnD. In the other region on the dielectric layer 107, no electrode is formed. This region is hereinafter referred to as an analog wiring region ZnA.

The dielectric layer 108 is provided on the upper surface of the dielectric layer 107. In the digital wiring region ZnD on the dielectric layer 108, an inner-layer ground electrode 403 is preferably provided. In the analog wiring region ZnA on the dielectric layer 108, the analog circuit electrode pattern 301 is preferably provided.

The dielectric layer 109 is provided on the upper surface of the dielectric layer 108. In the digital wiring region ZnD on the dielectric layer 109, the digital circuit electrode pattern 203 is preferably provided. In the analog wiring region ZnA on the dielectric layer 109, the analog circuit electrode pattern 301 is preferably provided.

The dielectric layer 110 is provided on the upper surface of the dielectric layer 109. In the digital wiring region ZnD on the dielectric layer 110, the inner-layer ground electrode 403 is preferably provided. In the analog wiring region ZnA on the dielectric layer 110, the analog circuit electrode pattern 301 is preferably provided.

The dielectric layer 111 is provided on the upper surface of the dielectric layer 110. In the digital wiring region ZnD on the dielectric layer 111, the digital circuit electrode pattern 203 is preferably provided. In the analog wiring region ZnA on the dielectric layer 111, the analog circuit electrode pattern 301 is preferably provided.

The dielectric layer 112 is provided on the upper surface of the dielectric layer 111. In the digital wiring region ZnD on the dielectric layer 112, the inner-layer ground electrode 403 is preferably provided. In the analog wiring region ZnA on the dielectric layer 112, no electrode is provided.

The dielectric layer 113 is provided on the upper surface of the dielectric layer 112. In the digital wiring region ZnD on the dielectric layer 113, the digital circuit electrode pattern 203 is preferably provided. In the analog wiring region ZnA on the dielectric layer 113, no electrode is provided.

The inner-layer ground electrodes 403 provided on the dielectric layers 108, 110, and 112 are connected to one another via a plurality of conductive vias 402TH provided in these layers. The inner-layer ground electrode 403 provided on the dielectric layer 108 is connected to the inner-layer ground electrode 401 on the upper surface of the dielectric layer 103 via the conductive vias 402TH formed at the dielectric layers 104 to 108. The inner-layer ground electrode 403 on the dielectric layer 112 is connected to an inner-layer ground electrode 402 to be described later through the conductive vias 402TH formed at the dielectric layers 113 to 115.

The laminate of the dielectric layers 104 to 113 and the dielectric layers 114 and 115 to be described later corresponds to an interlayer region according to a preferred embodiment of the present invention. The analog circuit portion 300 illustrated in FIG. 1 can be obtained with the analog wiring region ZnA on the dielectric layers 104 to 115 in the interlayer region.

In the interlayer region including the dielectric layers 104 to 115, the digital circuit electrode pattern 203 and the analog circuit electrode pattern 301 are disposed in different regions (the digital wiring region ZnD and the analog wiring region ZnA) so that they do not overlap in plan view of the laminate 100 (as viewed from the lamination direction). As a result, the electromagnetic coupling between the digital circuit electrode pattern 203 and the analog circuit electrode pattern 301 is prevented in the interlayer region.

Since the digital circuit electrode pattern 203 and the inner-layer ground electrode 403 are preferably alternately arranged along the lamination direction in the digital wiring region ZnD, the inner-layer ground electrode 403 is arranged closer to the digital circuit electrode pattern 203 than the analog circuit electrode pattern 301. Accordingly, the degree of the electromagnetic coupling between the digital circuit electrode pattern 203 and the inner-layer ground electrode 403 is greater than that of the electromagnetic coupling between the digital circuit electrode pattern 203 and the analog circuit electrode pattern 301. It is therefore possible to obtain a stable ground characteristic with respect to a digital circuit pattern. Furthermore, the electromagnetic coupling between the digital circuit electrode pattern 203 and the analog circuit electrode pattern 301 is more effectively prevented.

By providing the conductive vias 402TH in the digital wiring region ZnD, the ground characteristic of the digital circuit electrode pattern 203 is further improved.

The dielectric layer 114 is provided on the upper surface of the dielectric layer 113. On the dielectric layer 114, no electrode pattern is provided. Similar to the dielectric layers 104, 105, and 106, the dielectric layer 114 is used to adjust the spacing between each of the digital circuit electrode pattern 203 and the analog circuit electrode pattern 301 and the inner-layer ground electrode 402 on the dielectric layer 115.

The dielectric layer 115 is provided on the upper surface of the dielectric layer 114. The inner-layer ground electrode 402 (corresponding to the first inner-layer ground electrode according to a preferred embodiment of the present invention) is preferably provided on substantially the entire surface of the dielectric layer 115. The inner-layer ground electrode 402 is connected to the inner-layer ground electrode 403 via the conductive vias 402TH provided in the dielectric layers 113 to 115.

The inner-layer ground electrode 402 is also connected to the inner-layer ground electrode 401 on the dielectric layer 103 through conductive vias 400TH provided in the dielectric layers 104 to 115. The conductive vias 400TH are preferably arranged around the boundary surface between the digital wiring region ZnD and the analog wiring region ZnA in the interlayer region. By arranging the conductive vias 400TH at such a position, the ground is disposed between the digital circuit electrode pattern 203 and the analog circuit electrode pattern 301 with the conductive vias 400TH in the interlayer region. As a result, the electromagnetic coupling between the digital circuit electrode pattern 203 and the analog circuit electrode pattern 301 is more effectively prevented in the interlayer region. Although not illustrated in detail, when a plurality of conductive vias 400TH are arranged at predetermined intervals along the boundary surface between the digital wiring region ZnD and the analog wiring region ZnA (along the depth direction in FIG. 2) in the interlayer region, the electromagnetic coupling between the digital circuit electrode pattern 203 and the analog circuit electrode pattern 301 is more effectively prevented. The conductive vias 400TH around the boundary surface between the digital wiring region ZnD and the analog wiring region ZnA in the interlayer region may not be provided in accordance with characteristics and specifications.

The dielectric layer 116 is provided on the upper surface of the dielectric layer 115. The dielectric layer 117 is provided on the upper surface of the dielectric layer 116. A digital circuit electrode pattern 202 is provided on the substantially entire surfaces of the dielectric layers 116 and 117.

The dielectric layer 118 is provided on the upper surface of the dielectric layer 117, and is the uppermost layer in the laminate 100. A predetermined electrode pattern including IC mounting land electrodes 510 is preferably provided on the upper surface of the dielectric layer 118, that is, the top surface of the laminate 100. The baseband IC 21 and the front-end IC 22 are preferably mounted on the IC mounting land electrodes 510.

The laminate of the dielectric layers 116 to 118 corresponds to an upper layer region according to a preferred embodiment of the present invention. The digital circuit portion 200 illustrated in FIG. 1 can be obtained with the entire lower layer region, the entire upper layer region, the group of digital ICs mounted on the laminate, and the digital wiring region ZnD in the interlayer region.

As described previously, according to a preferred embodiment of the present invention, the laminated high-frequency module 10 including a digital circuit and an analog circuit can be provided using only the laminate 100 having the top surface on which digital ICs are mounted. Since the digital wiring region ZnD and the analog wiring region ZnA do not overlap in the interlayer region in plan view of the laminate, the electromagnetic coupling between the digital circuit and the analog circuit is prevented. As a result, noise from the digital circuit including the digital ICs is prevented from flowing into the analog circuit functioning as an RF circuit. This results in the size of a laminated high-frequency module being reduced while providing excellent communication characteristics.

The digital circuit electrode pattern 201 in the lower layer region and the digital circuit electrode pattern 202 in the upper layer region preferably overlap the analog circuit electrode pattern 301 in the interlayer region in plan view of the laminate 100. However, since the inner-layer ground electrode 401 is disposed between the digital circuit electrode pattern 201 in the lower layer region and the analog circuit electrode pattern 301 in the interlayer region and the inner-layer ground electrode 402 is disposed between the digital circuit electrode pattern 202 in the upper layer region and the analog circuit electrode pattern 301 in the interlayer region, the electromagnetic coupling between the digital circuit electrode pattern 201 in the lower layer region and the analog circuit electrode pattern 301 in the interlayer region and the electromagnetic coupling between the digital circuit electrode pattern 202 in the upper layer region and the analog circuit electrode pattern 301 in the interlayer region are also prevented.

Each of the digital circuit electrode pattern 201 on the dielectric layer 102 in the lower layer region and the digital circuit electrode pattern 202 on the dielectric layers 116 and 117 in the upper layer region preferably has a ratio of an electrode pattern formation area to a unit area of a dielectric layer greater than that of the digital circuit electrode pattern 203 provided on the dielectric layers 107, 109, 111, and 113 in the interlayer region. Thus, by providing the digital circuit electrode pattern 201 in the lower layer region and the digital circuit electrode pattern 202 in the upper layer region at a high density, not only the above-described prevention of electromagnetic coupling but also a reduction in the profile and size of the laminate 100 are achieved.

As illustrated in FIG. 2, in the analog wiring region ZnA on the dielectric layers 104 to 115, the conductive vias 400TH are preferably disposed on the side of the side surface of the laminate 100. By arranging the conductive vias 400TH at such a position, the analog circuit electrode pattern 301 is prevented from being electromagnetically coupled to an external circuit element and the digital circuit electrode pattern 202 in the upper layer region. The conductive vias 400TH in the analog wiring region ZnA on the side of the side surface of the laminate 100 may not be provided in accordance with characteristics and specifications.

The number of laminated layers, an electrode wiring pattern, a conductive via formation pattern are not limited to the above-described examples. For example, a digital line may be disposed on only a single layer in the interlayer region, a layer having no electrode pattern may not be provided, or the number of dielectric layers in each region may be changed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A laminated high-frequency module comprising:
a laminate including a plurality of dielectric layers each including an upper surface and an lower surface; and
a predetermined electrode pattern provided on at least one of the upper surface and the lower surface of each of the plurality of dielectric layers; wherein
the laminate includes an upper layer region including an upper surface of the laminate, a lower layer region including a lower surface of the laminate, and an interlayer region sandwiched between the upper layer region and the lower layer region of the laminate in a lamination direction thereof;
a first inner-layer ground electrode is provided on substantially an entire surface of one of the plurality of dielectric layers between the interlayer region and the upper layer region and on substantially an entire surface of one of the plurality of dielectric layers between the interlayer region and the lower layer region in plan view of the laminate;
a digital circuit electrode pattern is provided in the upper layer region and in the lower layer region in the laminate;
the digital circuit electrode pattern and an analog circuit electrode pattern are provided in the interlayer region in the laminate; and
in the interlayer region, a digital circuit electrode pattern formation region and an analog circuit electrode pattern formation region do not overlap in plan view of the laminate.

2. The laminated high-frequency module according to claim 1, wherein
in the interlayer region, the digital circuit electrode pattern is provided on at least two of the plurality of dielectric layers; and
a second inner-layer ground electrode is provided between the digital circuit electrode patterns provided on the at least two of the plurality of the dielectric layers in the interlayer region.

3. The laminated high-frequency module according to claim 2, wherein the second inner-layer ground electrode is provided in only the digital circuit electrode pattern formation region as viewed from the lamination direction.

4. The laminated high-frequency module according to claim 1, wherein an electrode formation density at which the digital circuit electrode pattern is provided in each of the upper layer region and the lower layer region is greater than that at which the digital circuit electrode pattern is provided in the interlayer region.

5. The laminated high-frequency module according to claim 1, wherein, in the interlayer region, a first conductive via connected to the first inner-layer ground electrode is provided between the digital circuit electrode pattern formation region and the analog circuit electrode pattern formation region.

6. The laminated high-frequency module according to claim 5, wherein, in the analog circuit electrode pattern formation region in the interlayer region, a second conductive via connected to the first inner-layer ground electrode is provided on a side of a side surface of the laminate as viewed from the lamination direction.

7. The laminated high-frequency module according to claim 5, wherein, in the digital circuit electrode pattern formation region in the interlayer region, a plurality of third conductive vias each connected to the first inner-layer ground electrode or the second inner-layer ground electrode are provided.
